(19) United States
(12) Patent Application Publication
(10) Pub. No.: US 2026/0238223 A1
(43) Pub. Date: Aug. 13, 2026

(54) FLAT SPOT SUPPRESSION IN SIGMA DELTA CONVERTERS

(71) Applicant: Cypress Semiconductor Corporation, San Jose, CA (US)

(72) Inventors: Peng CHEN, Ballincollig (IE); Gaurav PANCHANAN, Cork (IE)

(73) Assignee: Cypress Semiconductor Corporation, San Jose, CA (US)

(21) Appl. No.: 19/048,402

(22) Filed: Feb. 7, 2025

(51) Int. Cl. H03M 3/00

(52) U.S. Cl. CPC H03M 3/496; H03M 3/328

(57) ABSTRACT

A sigma delta converter structure comprises a sampling stage that comprises a sampling capacitor. The sigma delta converter structure further comprises a modulation stage that comprises a modulation capacitor in series with the sampling capacitor, a reference capacitor, and a unit gain buffer having a non-inverting input terminal, an inverting input terminal and an output terminal. The non-inverting input terminal can be connectable to the reference capacitor and the modulation capacitor, and the output terminal can be connected to the inverting input terminal.

### FIELD OF THE INVENTION

Embodiments of the present disclosure relate generally to sigma delta converters. More specifically, embodiments of the present disclosure relate to flat spot suppression in a sigma delta converter.

### BACKGROUND

A sigma delta converter is a type of analog-to-digital converter (ADC) that converts analog signals into digital signals with high precision and accuracy. In a multi-stage (sampling stage, modulation stage) sigma delta converter, which can be used in different applications such as resistive sensing, current sensing, capacitive sensing or any sensor front-end that utilizes multi-stage sigma delta converter structures, a flat spot refers to a region or point in the converter's output where the response becomes non-linear or less sensitive to changes in the input. This can occur due to various reasons, such as design limitations, material properties, environmental factors (e.g., humidity, temperature, or nearby conductive objects can influence the sensor's performance), and/or signal processing. Flat spots can be problematic as they can affect the accuracy and reliability of the converter, particularly in applications that require precise touch or proximity detection.

FIG. 1A is a plot diagram showing the relationship between a capacitance under test in a typical capacitive sensing system and the digital output of the capacitance under test. The capacitance under test refers to a specific capacitance being measured or monitored by the capacitive sensing system. The output of the capacitance under test refers to a change in capacitance that is detected and measured by the system.

Referring to FIG. 1A, plot 100A shows an example flat spot 101 that induces a large insensitive zone as the capacitance varies. As can be seen, in the insensitive zone induced by flat spot 101, the output of the capacitance under test does not change across different input values of the capacitance under test. This lack of change in the output negatively impacts the accuracy and reliability of the capacitive sensing system.

Generally, a flat spot is caused by an integrator gain in the sigma delta converter. For example, referring to FIG. 1B, which illustrates a transfer function of a first order sigma delta system, transfer function 100B describes the relationship between the input (changes in capacitance) and the output (the converter's response) of the sigma delta system.

As shown, transfer function 100B includes, among other aspects, an integrator 111 that includes an integrator 113 (e.g., modulation capacitor C_{mod}) having an integrator gain that exists in both the sampling capacitor (Cₛ) sampling stage and the reference capacitor (C_{ref}) modulation stage. Integrator 113 can be a passive or active integrator. For active integrator, the non-ideality of the op-amp gain can lead to a flat spot. In general, the value of the integrator 113 in transfer function 100B is 1. Unfortunately, in some instances (e.g., electrode design issues, shielding or ground problems, material homogeneity, environmental factors, manufacturing defects, signal processing limitations, etc.), the value of the integrator 113 can fall below 1, thereby causing a flat spot, such as flat spot 101.

### BRIEF DESCRIPTION OF THE DRAWINGS

Embodiments of the disclosure are illustrated by way of example and not limitation in the figures of the accompanying drawings in which like references indicate similar elements.

FIG. 1A is a plot diagram showing the relationship between a capacitance under test in a typical capacitive sensing system and the digital output of the capacitance under test.

FIG. 1B is a block diagram illustrating a transfer function of a first order sigma delta system.

FIG. 2 is a schematic diagram of a sigma delta converter circuit with a dithering capacitor circuit.

FIG. 3A is a schematic diagram illustrating a sigma delta converter circuit operating in Cₛ sampling phase.

FIG. 3B is a schematic diagram illustrating the sigma delta converter circuit of FIG. 3A operating in C_{ref} modulation phase.

FIG. 4A is a diagram illustrating two different voltages between which a reference capacitor C_{ref} of FIGS. 3A-3B is connected in the Cₛ sampling phase.

FIG. 4B is a diagram illustrating two different voltages between which the reference capacitor C_{ref} of FIGS. 3A-3B is connected in the C_{ref} modulation phase.

FIG. 5 is a schematic diagram of a sigma delta converter circuit according to an embodiment.

FIG. 6A is a diagram illustrating two different voltages between which a reference capacitor C_{ref} of FIG. 5 is connected in Cₛ sampling phase.

FIG. 6B is a diagram illustrating two different voltages between which the reference capacitor C_{ref} of FIG. 5 is connected in C_{ref} modulation phase.

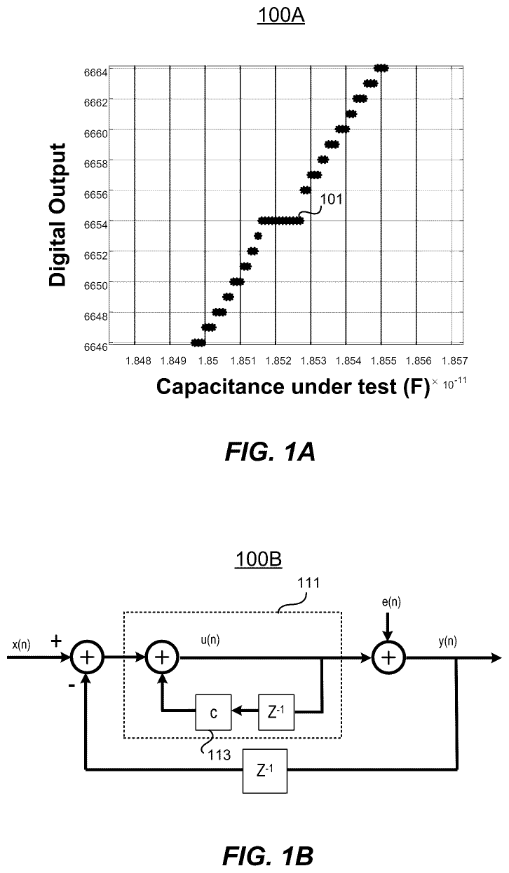

### DETAILED DESCRIPTION

Various embodiments and aspects of the inventions will be described with reference to details discussed below, and the accompanying drawings will illustrate the various embodiments. The following description and drawings are illustrative of the invention and are not to be construed as limiting the invention. Numerous specific details are described to provide a thorough understanding of various embodiments of the present invention. However, in certain instances, well-known or conventional details are not described in order to provide a concise discussion of embodiments of the present inventions.

Reference in the specification to “one embodiment” or “an embodiment” means that a particular feature, structure, or characteristic described in conjunction with the embodiment can be included in at least one embodiment of the invention. The appearances of the phrase “in one embodiment” in various places in the specification do not necessarily all refer to the same embodiment.

According to one aspect, a sigma delta converter structure is provided. The sigma delta converter structure comprises a sampling stage that comprises a sampling capacitor. The sigma delta converter structure further comprises a modulation stage that comprises a modulation capacitor in series with the sampling capacitor, a reference capacitor, and a unit gain buffer having a non-inverting input terminal, an inverting input terminal and an output terminal. The non-inverting input terminal may be connectable to the reference capacitor and the modulation capacitor, and the output terminal may be connected to the inverting input terminal.

According to another aspect, a flat spot suppression structure for a sigma delta converter system is provided. The flat spot suppression structure comprises a reference capacitor and a unit gain buffer having a non-inverting input terminal, an inverting input terminal and an output terminal. The non-inverting input terminal may be connectable to the reference capacitor through a third switching device. The inverting input terminal may be in series with a fourth switching device and a fifth switching device. The output terminal may be connected to the inverting input terminal and connectable to a node between the third switching device and the reference capacitor through a sixth switching device. The reference capacitor may be connected to a node between the fourth switching device and the fifth switching device.

Typically, a dithering technique can be applied to suppress flat spots. An implementation of the dithering technique is to create a separate dithering capacitor to suppress flat spots, such as flat spot 101 discussed above. The dithering capacitor path serves to introduce pre-defined noise or a small perturbation in the sigma delta system to improve the performance and accuracy of the system by breaking the limited cycles in the sigma delta system. Dithering can help in overcoming issues such as quantization errors, non-linearity, and hysteresis in sigma delta systems.

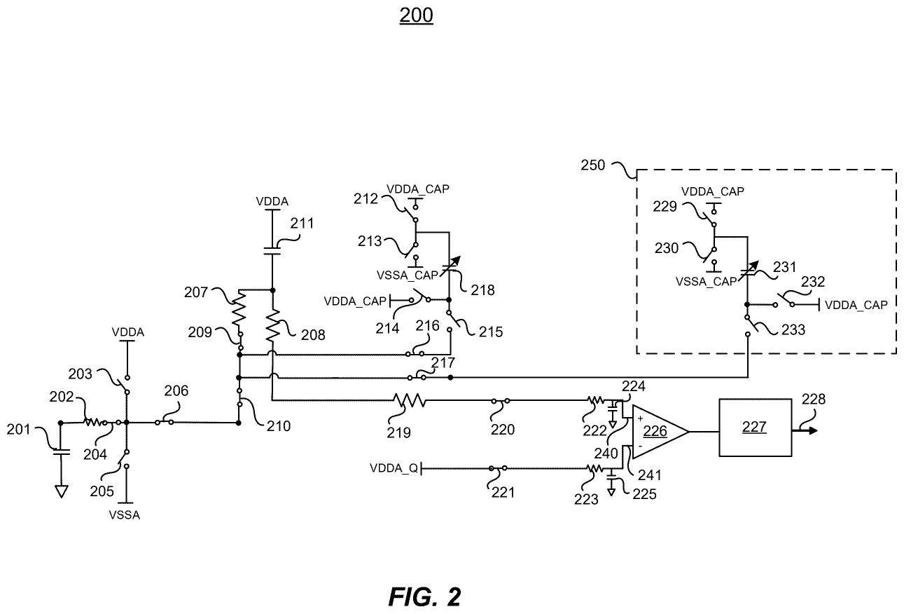

For example, in FIG. 2, a sigma delta converter circuit or structure with a dithering capacitor circuit is illustrated. Referring to FIG. 2, sigma delta converter circuit 200 includes switches (or switching devices) 203-206, 209-210, 212-217, 220-221 (e.g., metal-oxide-semiconductor (MOS) switches), resistors 202, 207-208, 219, 222-223, a sampling capacitor (Cₛ) 201, a modulation capacitor (C_{mod}) 211, a reference capacitor (C_{ref}) 218, filter capacitors 224-225, a comparator 226, a counter 227, and a dithering capacitor circuit 250. Switches 203-206 and 209-210 can be controlled by a multiplexer, e.g., an analog multiplexer (AMUX), while switches 212-215 can be controlled by a clock reference (CLK_REF).

As shown, switches 203 and 205 are connected in series between an analog power supply voltage (VDDA) and an analog ground (VSSA). Sampling capacitor 201, resistor 202 and switch 204 are connected in series between ground (GND) and a node between switches 203 and 205. Switches 206, 210 and 209, resistor 207 and modulation capacitor 211 are connected in series between VDDA and the node between switches 203 and 205. Modulation capacitor 211, resistors 208 and 219, switch 220 and resistor 222 are connected in series between VDDA and an input terminal 240 of comparator 226 (e.g., non-inverting terminal). As shown, the resistor 207 may include one terminal connected to the switch 209 and another terminal connected to a node between the modulation capacitor 211 and the resistor 208. The resistor 222 is also connected in series with the filter capacitor 224 between the switch 220 and GND to form a filter, such as a low-pass filter, at the input terminal 240. Furthermore, switch 221 is connected in series with resistor 223 between a particular analog power supply voltage (VDDA_Q) and an input terminal 241 of the comparator 226 (e.g., inverting terminal). The resistor 223 is also connected in series with the filter capacitor 225 between the switch 221 and GND to form another filter, such as low-pass filter, at the input terminal 241.

Comparator 226 provides comparator output signals (e.g., complementary output signals, pulse signals, etc.) to counter 227 by comparing input signals applied to the input terminals 240-241. Comparator 226 can be differential amplifier, such as operational amplifier (op-amp), latch comparator, etc. Counter 227 (e.g., N-bit counter) may count the comparator output signals from the comparator 226 by using, for example, the binary output (high or low) of the comparator 226 as a trigger to increment the counter value. In other words, when the comparator 226 detects a condition where one input (e.g., input from input terminal 240 or 241) is greater than or less than the other (depending on the configuration), it may output a pulse signal which is then counted by the counter 227. Based on the comparator output signals, counter 227 produces an n-bit binary number as an output (raw count) 228.

With continued reference to FIG. 2, switches 212-213 are connected in series between an analog power supply voltage (VDDA_CAP) and an analog ground (VSSA_CAP). Switches 214-216 are connected in series between VDDA_CAP and a node between switches 209-210. As shown, one terminal of the reference capacitor 218 (top plate) is connected to a node between switches 212-213 and another terminal of the reference capacitor 218 (bottom plate) is connected to a node between switches 214-215. The switch 217 has one terminal connected to the node between switches 209-210 and another terminal connected to the dithering capacitor circuit 250.

In FIG. 2, dithering capacitor circuit 250 includes switches 229-230 and 232-233, and a dithering capacitor (C_{dither}) 231. Switches 229-230 are connected in series between VDDA_CAP and VSSA_CAP, and switches 232-233 are connected in series between VDDA_CAP and the switch 217. The dithering capacitor 231 has one terminal (top plate) connected to a node between the switches 229-230 and another terminal (bottom plate) connected to a node between 232-233.

In sigma delta converter circuit 200, while the additional dithering path created by the dithering capacitor circuit 250 can effectively suppress the flat spot, the dithering capacitor circuit 250, however, demands additional power consumption and additional area on the sigma delta converter circuit 200, and it also generates additional noise. Furthermore, dithering can cause gain deviation in the transfer function of the sigma delta converter circuit 200, and as such, capacitance to digital conversion needs to be calibrated, thereby causing additional expense.

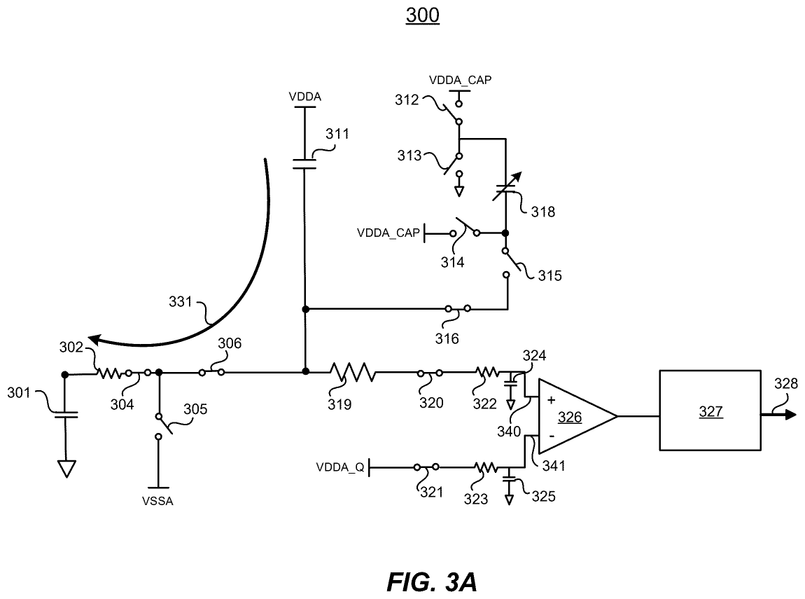

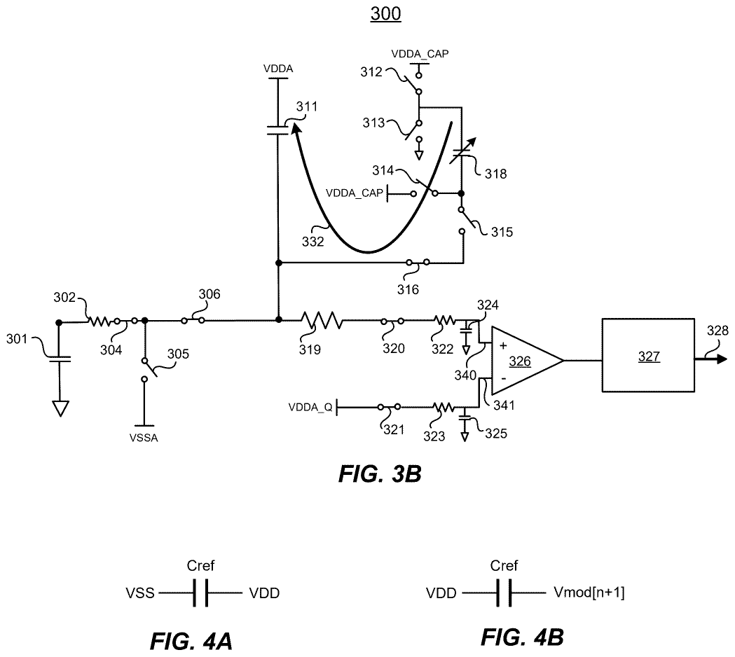

FIGS. 3A-3B are schematic diagrams of a sigma delta converter circuit operating in a sampling phase and a modulation phase. In FIGS. 3A-3B, sigma delta converter circuit 300 includes switches (or switching devices) 304-306, 312-316, 320-321 (e.g., MOS switches), resistors 304, 319, 322-323, a sampling capacitor (Cₛ) 301, a modulation capacitor (C_{mod}) 311, a reference capacitor (C_{ref}) 318, filter capacitors 324-325, a comparator 326, and a counter 327. Switches 304-306 and 209-210 can be controlled by a multiplexer, e.g., an AMUX, while switches 312-315 can be controlled by a clock reference (CLK_REF).

Referring to FIGS. 3A-3B, sampling capacitor 301, resistor 302 and switches 304-305 are connected in series between GND and VSSA. Modulation capacitor 311, switch 306 and switch 305 are also connected in series between VDDA and VSSA. Modulation capacitor 311, resistor 319, switch 320 and resistor 322 are connected in series between VDDA and an input terminal 340 of comparator 326 (e.g., non-inverting terminal). The resistor 322 is also connected in series with the filter capacitor 324 between the switch 320 and GND to form a filter, such as a low-pass filter, at the input terminal 340. Moreover, switch 321 is connected in series with resistor 323 between VDDA_Q and an input terminal 341 of the comparator 326 (e.g., inverting terminal). The resistor 323 is also connected in series with the filter capacitor 325 between the switch 321 and GND to form another filter, such as low-pass filter, at the input terminal 341.

Comparator 326 provides comparator output signals (e.g., complementary output signals, pulse signals, etc.) to counter 327 by comparing input signals applied to the input terminals 340-341. Comparator 326 can be differential amplifier, such as op-amp, latch comparator, etc. Counter 327 (e.g., N-bit counter) may count the comparator output signals from the comparator 326 by using, for example, the binary output (high or low) of the comparator 326 as a trigger to increment the counter value. In other words, when the comparator 326 detects a condition where one input (e.g., input from input terminal 340 or 341) is greater than or less than the other (depending on the configuration), it may output a pulse signal which is then counted by the counter 327. Based on the comparator output signals, counter 327 produces an n-bit binary number as an output (raw count) 328.

With continued reference to FIGS. 3A-3B, switches 312-313 are connected in series between VDDA_CAP and GND. Switches 314-316 are connected in series between VDDA_CAP and a node between capacitor 311 and switch 306. As shown, one terminal of the reference capacitor 318 (top plate) is connected to a node between switches 312-313 and another terminal of the reference capacitor 318 (bottom plate) is connected to a node between switches 314-315.

The sigma delta converter circuit 300 operates in two phases per sampling period. In the Cₛ sampling phase (or PH0), switches 313-314 and 305 are closed while switches 312, 315 and 306 are open. Thus, charges flow out from the modulation capacitor (C_{mod}) 311 and into the sampling capacitor (Cₛ) 301 due to Cₛ sampling (as indicated by flow path 331 in FIG. 3A). In this sampling phase, the reference capacitor 318 is connected between VDD and VSS (see FIG. 4A), and the voltage across C_{mod} (V_{mod}) can be represented as follows:

$${V}_{m o d} [ n + 1 ] = \frac{{C}_{m o d}}{{C}_{m o d} + {C}_{s}} \cdot {V}_{m o d} [ n ] , \qquad ( 1 )$$

$$where \frac{{C}_{m o d}}{{C}_{m o d} + {C}_{s}} represents the integratot gain .$$

In C_{ref} modulation phase (or PH1), switches 313-314 and 305 are open while switches 312, 315 and 306 are closed. Thus, charges flow out from the reference capacitor 318 and into the modulation capacitor 311 due to C_{ref} modulation (as indicated by flow path 332 in FIG. 3B). In this modulation phase, the reference capacitor 318 is connected between V_{mod}[n+1] and VDD (see FIG. 4B), V_{mod} can be represented as follows:

$${V}_{m o d} [ m + 1 ] = \frac{{C}_{m o d}}{{C}_{mod} + {C}_{ref}} \cdot {V}_{m o d} [ m ] + \frac{2 {C}_{r e f}}{{C}_{mod} + {C}_{ref}} \cdot {V}_{D D} , \qquad ( 2 )$$

$$where \frac{{C}_{m o d}}{{C}_{mod} + {C}_{ref}}$$

represents the integrator gain.

In the sigma delta converter circuit 300, the integrator (C_{mod}) induces leakage both from the Cₛ sampling phase and the C_{ref} modulation phase. Therefore, integrator gains are less than 1 in both phases, and as such, flat spots are likely to produce.

To suppress the flat spots without using a separate dithering capacitor path, the integrator gain at the C_{ref} modulation phase needs to be slightly larger than 1 in order to adjust the overall integrator gain. For example, the integrator gain

$$\frac{{C}_{m o d}}{{C}_{m o d} + {C}_{s}}$$

at the Cₛ sampling phase may remain unchanged. However, the integrator gain at the C_{ref} modulation phase may be modified to:

$$\frac{{C}_{mod} + \frac{A}{1 + A} {C}_{ref}}{{C}_{mod} + \frac{A}{1 + A} {C}_{ref}}$$

where A represents an amplifier gain. Thus, V_{mod} (a voltage across C_{mod}) in the modulation phase can be represented as:

$${V}_{m o d} [ m + 1 ] = \frac{{C}_{mod} + \frac{A}{1 + A} {C}_{ref}}{{C}_{mod} + \frac{A}{1 + A} {C}_{ref}} \cdot {V}_{m o d} [ m ] \qquad ( 3 )$$

Accordingly, to suppress the flat spots, a unit gain buffer can be added without substantial altering of the sigma delta converter circuit 300.

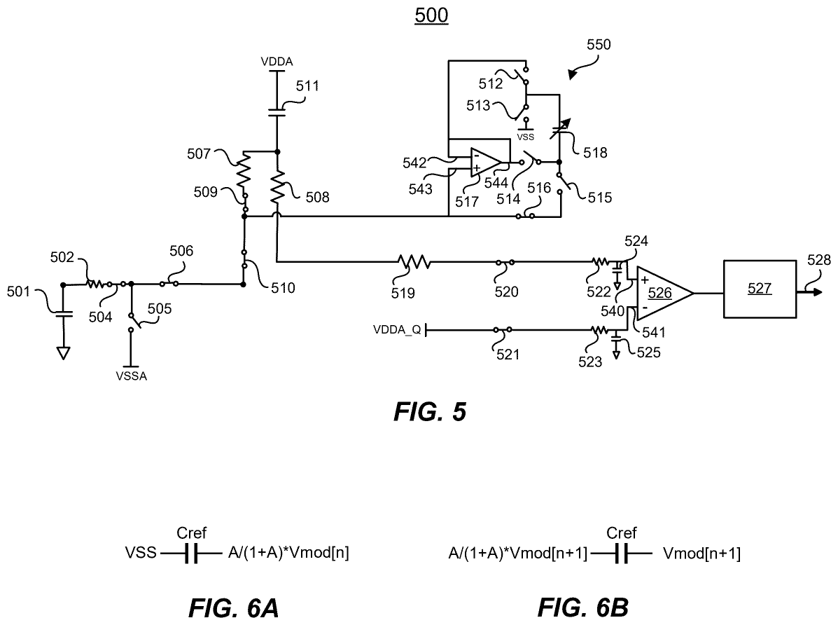

FIG. 5 is a schematic diagram of a sigma delta converter circuit or structure according to an embodiment. Referring to FIG. 5, sigma delta converter circuit 500 may include, but is not limited to, switches (or switching devices) 504-506, 509-510, 512-516, 520-521 (e.g., MOS switches), resistors 502, 507-508, 519, 522-523, a sampling capacitor (Cₛ) 501, a modulation capacitor (C_{mod}) 511, a reference capacitor (C_{ref}) 518, filter capacitors 524-525, a comparator 526, a counter 527, and a flat spot suppression circuit 550. Switches 504-506 and 509-510 can be controlled by a multiplexer, e.g., an analog multiplexer (AMUX), while switches 512-515 can be controlled by a clock reference (CLK_REF). In some embodiments, the sigma delta converter circuit 500 may be a two-stage (e.g., sampling stage and modulation stage) first order sigma delta system. It is noted that in some embodiments, multiple sigma delta converters 500 can be used in a sigma delta system where each integrator gain can be modified as described above.

As shown, sampling capacitor 501, resistor 502 and switches 504-505 may be connected in series between ground (GND) and VSSA. Switches 505, 506, 510 and 509, resistor 507 and modulation capacitor 511 may be connected in series between VDDA and VSSA. Modulation capacitor 511, resistors 508 and 519, switch 520 and resistor 522 may be connected in series between VDDA and an input terminal 540 of comparator 526 (e.g., non-inverting terminal). As shown, the resistor 507 may include one terminal connected to the switch 509 and another terminal connected to a node between the modulation capacitor 511 and the resistor 508. The resistor 522 may also be connected in series with the filter capacitor 524 between the switch 520 and GND to form a filter, such as a low-pass filter, at the input terminal 540. Furthermore, switch 521 may be connected in series with resistor 523 between VDDA_Q and an input terminal 541 of the comparator 526 (e.g., inverting terminal). The resistor 523 may also be connected in series with the filter capacitor 525 between the switch 521 and GND to form another filter, such as low-pass filter, at the input terminal 541.

In some embodiments, comparator 526 may provide comparator output signals (e.g., complementary output signals, pulse signals, etc.) to counter 527 by comparing input signals applied to the input terminals 540-541. In an embodiment, comparator 526 can be a differential amplifier, such as an op-amp, latch comparator, etc. Counter 527 (e.g., N-bit counter) may count the comparator output signals produced by the comparator 526 by using, for example, the binary output (high or low) of the comparator 526 as a trigger to increment the counter value. In other words, when the comparator 526 detects a condition where one input (e.g., input from input terminal 540 or 541) is greater than or less than the other (depending on the configuration), it may output a pulse signal which is then counted by the counter 527. Based on the comparator output signals, counter 527 produces an n-bit binary number as an output (raw count) 528, where n is a positive integer.

With continued reference to FIG. 5, flat spot suppression circuit 550 may be connected to a node between switches 509-510. Flat spot suppression circuit 550 may include switches 512-516, a unit gain buffer 517 (e.g., op-amp, latch comparator, etc.), and a reference capacitor (C_{ref}) 518.

Switches 512-513 may be connected in series between VSS and an input terminal 542 of the unit gain buffer 517 (e.g., inverting terminal). The reference capacitor 518, switch 515, and switch 516 may be connected in series between a node between switches 512-513 and an input terminal 543 of the unit gain buffer 517 (e.g., non-inverting terminal). The input terminal 543 may also be connected to a node between switches 509-510.

As shown, the output terminal 544 of the unit gain buffer 517 may be shorted or connected to the input terminal 542. One terminal of the switch 514 may be connected to the output terminal 544 and another terminal of the switch 514 may be connected to a node between reference capacitor 518 and switch 515.

In operation, the sigma delta converter circuit 500 operates in two phases per sampling period. In the Cₛ sampling phase (or PH0), switches 505, 513-514 are closed while switches 506, 512 and 515 are open. In this sampling phase, the reference capacitor 518 may be connected between A/(1+A)*V_{mod}[n] and VSS (see FIG. 6A).

In C_{ref} modulation phase (or PH1), switches 505, 513-514 are open while switches 506, 512 and 515 are closed. In this modulation phase, the reference capacitor 518 may be connected between V_{mod}[n+1] and A/(1+A)*V_{mod}[n+1] (see FIG. 6B).

Various units, circuits, or other components may be described or claimed as “configured to” or “configurable to” perform a task or tasks. In such contexts, the phrase “configured to” or “configurable to” is used to connote structure by indicating that the units/circuits/components include structure (e.g., circuitry) that performs the task or tasks during operation. As such, the unit/circuit/component can be said to be configured to perform the task, or configurable to perform the task, even when the specified unit/circuit/component is not currently operational (e.g., is not on). The units/circuits/components used with the “configured to” or “configurable to” language include hardware—for example, circuits, memory storing program instructions executable to implement the operation, etc. Reciting that a unit/circuit/component is “configured to” perform one or more tasks, or is “configurable to” perform one or more tasks, is expressly intended not to invoke 35 U.S.C. 112(f) or 35 U.S.C. 112, sixth paragraph, for that unit/circuit/component.

In the foregoing specification, embodiments of the invention have been described with reference to specific exemplary embodiments thereof. It will be evident that various modifications may be made thereto without departing from the broader spirit and scope of the invention as set forth in the following claims. The specification and drawings are, accordingly, to be regarded in an illustrative sense rather than a restrictive sense.

What is claimed is:

1. A sigma delta converter structure, comprising:
a sampling stage comprising a sampling capacitor; and
a modulation stage comprising:
a modulation capacitor in series with the sampling capacitor,
a reference capacitor, and
a unit gain buffer having a non-inverting input terminal, an inverting input terminal and an output terminal, wherein the non-inverting input terminal is connectable to the reference capacitor and the modulation capacitor, and the output terminal is connected to the inverting input terminal.

2. The sigma delta converter structure of claim 1, wherein:
the sampling capacitor is in series with a first switching device;
the modulation capacitor is in series with the first switching device and a second switching device disposed between the modulation capacitor and the first switching device;
the non-inverting input terminal is connectable to the reference capacitor through a third switching device, the inverting input terminal is in series with a fourth switching device and a fifth switching device, the output terminal is connectable to a node between the third switching device and the reference capacitor through a sixth switching device, and the reference capacitor is connected to a node between the fourth switching device and the fifth switching device.

3. The sigma delta converter structure of claim 2, further comprising an integration stage comprising:
a comparator having a non-inverting input terminal and an inverting input terminal, the comparator configured to compare input signals applied to the non-inverting and inverting input terminals and provide comparator output signals based on the comparison; and
a counter configured to receive the comparator output signals from the comparator and produce an n-bit binary number as an output based on the comparator output signals, wherein n is a positive integer;
wherein:
a first filter connected to the non-inverting input terminal of the comparator and connectable to the modulation capacitor through a seventh switching device; and
a second filter connected to the inverting input terminal of the comparator and connectable to an analog power supply voltage through an eighth switching device.

4. The sigma delta converter structure of claim 2, wherein the non-inverting input terminal of the unit gain buffer is connected to a node between the modulation capacitor and the second switching device.

5. The sigma delta converter structure of claim 2, wherein
the modulation capacitor is further in series with a first resistor, a ninth switching device, and a tenth switching device;
the first resistor and the ninth and tenth switching devices are disposed between the modulation capacitor and the second switching device.

6. The sigma delta converter structure of claim 5, wherein the non-inverting input terminal of the unit gain buffer is connected to a node between the ninth switching device and the tenth switching device.

7. The sigma delta converter structure of claim 3, wherein
the modulation capacitor is further in series with a second resistor, a third resistor, and the seventh switching device;
the second resistor, the third resistor and the seventh switching device are disposed between the modulation capacitor and the first filter.

8. The sigma delta converter structure of claim 2, wherein
the sampling capacitor is further in series with a fourth resistor and an eleventh switching device;
the fourth resistor and the eleventh switching device are disposed between the sampling capacitor and the first switching device.

9. The sigma delta converter structure of claim 2, wherein in sampling phase, the first, fifth, and sixth switching devices are closed, and the second, third, and fourth switching devices are open.

10. The sigma delta converter structure of claim 9, wherein in the sampling phase, the reference capacitor is connected between A/(1+A)*V_{mod} and VSS, wherein A is an amplifier gain of the unit gain buffer, V_{mod} is a voltage across the modulation capacitor, and VSS is an analog ground.

11. The sigma delta converter structure of claim 10, wherein in modulation phase, the first, fifth, and sixth switching devices are open, and the second, third, and fourth switching devices are closed.

12. A flat spot suppression structure for a sigma delta converter system, the flat spot suppression structure comprising:
a reference capacitor; and
a unit gain buffer having a non-inverting input terminal, an inverting input terminal and an output terminal, wherein the non-inverting input terminal is connectable to the reference capacitor through a third switching device, the inverting input terminal is in series with a fourth switching device and a fifth switching device, the output terminal is connected to the inverting input terminal and connectable to a node between the third switching device and the reference capacitor through a sixth switching device, and the reference capacitor is connected to a node between the fourth switching device and the fifth switching device.

13. The flat spot suppression structure of claim 12, wherein the non-inverting input terminal of the unit gain buffer is connected to a node between a modulation capacitor and a second switching device.

14. The flat spot suppression structure of claim 13, wherein
the modulation capacitor is in series with a first switching device and the second switching device;
the second switching device is disposed between the modulation capacitor and the first switching device;
the first switching device is in series with a sampling capacitor.

15. The flat spot suppression structure of claim 14, wherein
the modulation capacitor is further in series with a first resistor, a ninth switching device, and a tenth switching device;
the first resistor and the ninth and tenth switching devices are disposed between the modulation capacitor and the second switching device.

16. The flat spot suppression structure of claim 15, wherein the non-inverting input terminal of the unit gain buffer is connected to a node between the ninth switching device and the tenth switching device.

17. The flat spot suppression structure of claim 14, wherein in sampling phase, the first, fifth, and sixth switching devices are closed, and the second, third, and fourth switching devices are open.

18. The flat spot suppression structure of claim 17, wherein in the sampling phase, the reference capacitor is connected between A/(1+A)*V_{mod} and VSS, wherein A is an amplifier gain of the unit gain buffer, V_{mod} is a voltage across the modulation capacitor, and VSS is an analog ground.

19. The flat spot suppression structure of claim 18, wherein in modulation phase, the first, fifth, and sixth switching devices are open, and the second, third, and fourth switching devices are closed.

20. The flat spot suppression structure of claim 19, wherein in the modulation phase, the reference capacitor is connected between V_{mod} and A/(1+A)*V_{mod}.
